(19) United States
(12) Patent Application Publication
(10) Pub. No.: US 2022/0384236 A1
(43) Pub. Date: Dec. 1, 2022

(54) Chip transfer assembly and manufacturing method therefor, chip transfer method, and display backplane

(71) Applicant: CHONGQING KONKA PHOTOELECTRIC TECHNOLOGY RESEARCH INSTITUTE CO., LTD., Chongqing (CN)

(72) Inventor: Feng ZHAI, Chongqing (CN)

(21) Appl. No.: 17/771,509

(22) PCT Filed: Aug. 13, 2020
(86) PCT No.: PCT/CN2020/108881

§ 371 Date: Apr. 25, 2022

(51) Int. Cl. H01L 21/683; H01L 25/075; H01L 23/00; H01L 33/50; H01L 33/62

(52) U.S. Cl. CPC H01L 21/6835; H01L 25/0753; H01L 24/95; H01L 24/81; H01L 33/501; H01L 33/62; H01L 24/16; H01L 2224/16227; H01L 2224/81005; H01L 2224/81815; H01L 2224/95001; H01L 2224/81192; H01L 2933/0041; H01L 2933/0066; H01L 2221/68368; H01L 2221/68377; H01L 2221/68381

(57) ABSTRACT

A chip transfer assembly and a manufacturing method therefor, a chip transfer method, and a display backplane. The chip transfer assembly comprises a transfer substrate (1); a porous adhesive layer (2) formed on the transfer substrate, first pores (21) being distributed in the porous adhesive layer; and at least one colloid protrusions (3) formed on the porous adhesive layer, the colloid protrusions having light transmittance, and second pores (31) used for accommodating luminescent conversion particles (4) being distributed in the colloid protrusions; after an LED chip (7) is transferred to a chip soldering zone, the colloid protrusions separate from the porous adhesive layer and remain on the LED chip to form a luminescent conversion layer.

### TECHNICAL FIELD

The disclosure relates to the field of semiconductor devices, and in particular, to a chip transfer assembly and a manufacturing method therefor, a chip transfer method, and a display backplane.

### BACKGROUND

Micro-Light Emitting Diode (Micro-LED) is a new generation of a display technology. Compared with existing liquid crystal display, Micro-LED has a higher photoelectric efficiency, a higher brightness, and a higher contrast, and can implement flexible display by combining with a flexible panel.

A Micro-LED display panel includes a plurality of pixel areas. Each pixel area includes a red LED chip, a blue LED chip, and a green LED chip. During the manufacturing of the display panel, the blue LED chip is required to be first transferred to a display backplane of the display panel from a growth substrate, and then a red quantum dot (QD) film and a green QD film are separately manufactured on the blue LED chip that needs to form red light and green light on the display backplane, to convert light emitted by the corresponding blue LED chip into the corresponding red light and green light. The above method of first transferring the blue LED chip to the display backplane and then separately manufacture the film for luminescent conversion on the blue LED chip is relatively tedious in process and low in efficiency, resulting in high manufacturing cost of the display panel.

Therefore, the way of simplifying the manufacturing of the display panel, enhancing manufacturing efficiency, and reducing costs is an urgent problem to be resolved.

### SUMMARY

In view of the disadvantages in the related art, this application is intended to provide a chip transfer assembly and a manufacturing method therefor, a chip transfer method, and a display backplane, to resolve problems of tedious manufacturing, low manufacturing efficiency, and high costs of a display panel in the related art.

### Solution to the Problem

### Technical Solution

A chip transfer assembly includes a transfer substrate.

A porous adhesive layer is formed on the transfer substrate. First pores are distributed in the porous adhesive layer.

At least one colloid protrusion is formed on the porous adhesive layer. The colloid protrusion has a light transmittance. Second pores are distributed in the colloid protrusion. A size of each second pore matches a size of a luminescent conversion particle and the size of each second pore is less than a size of each first pore.

The second pore is configured to accommodate the luminescent conversion particle during transfer of a Light-Emitting Diode (LED) chip. The colloid protrusion is configured to be attached to a light-emitting surface of a to-be-transferred LED chip and then to adsorb the LED chip under the action of cooling after heating during transfer of the LED chip. The colloid protrusion is further configured to form a separation surface on a surface that is in contact with the porous adhesive layer during soldering of the heated LED chip after the adsorbed LED chip is transferred to a chip soldering zone, so as to separate from the porous adhesive layer and retain on the light-emitting surface of the LED chip.

Based on a same concept of the disclosure, this application further provides a method for manufacturing a chip transfer assembly, including the following operations.

A transfer substrate is provided.

The porous adhesive layer is formed on the transfer substrate. First pores are distributed in the porous adhesive layer.

The colloid protrusion is formed on the porous adhesive layer. The colloid protrusion has a light transmittance. Second pores are distributed in the colloid protrusion. A size of each second pore matches a size of a luminescent conversion particle and is less than a size of each first pore.

The method for manufacturing a chip transfer assembly is simple and convenient in manufacturing, high in manufacturing efficiency, and low in cost.

Based on a same concept of the disclosure, this application further provides a chip transfer method, including the following operations.

A colloid protrusion of the foregoing chip transfer assembly is infiltrated into luminescent conversion particles, to cause the luminescent conversion particles to enter second pores.

The colloid protrusion is attached to a light-emitting surface of the to-be-transferred LED chip, and is cooled after being heated to a first preset temperature, to cause the colloid protrusion to adsorb the LED chip, so as to pick up the LED chip.

The LED chip picked up by the colloid protrusion is transferred to a chip soldering zone provided with a solder in advance, the solder is melted to solder the LED chip by heating a temperature to a second preset temperature, and a separation surface is formed on a contact surface between the colloid protrusion and the porous adhesive layer under the action of a heat effect during this process, so as to separate the colloid protrusion from the porous adhesive layer and retain the colloid protrusion on the light-emitting surface of the LED chip.

In the above chip transfer method, during the transferring of the LED chip to the chip soldering zone, the transferring of the chip and the manufacturing of a luminescent conversion layer are completed simultaneously. In this way, the luminescent conversion layer is no longer required to be separately manufactured after the LED chip is transferred to the chip soldering zone of a display backplane. Therefore, a manufacturing process of a display panel is simplified, manufacturing efficiency is enhanced, and a manufacturing cost is reduced.

Based on a same concept of the disclosure, this application further provides a display panel. The display panel includes a display backplane and a plurality of LED chips. A plurality of chip soldering zones are disposed on the display backplane. The plurality of LED chips are respectively transferred to the chip soldering zones to achieve bonding by means of the foregoing chip transfer method.

The above display panel adopts a manner of transferring the LED chip more simply and efficiently and manufacturing a light conversion film, which causes the manufacturing of the display panel more convenient and efficient, thereby shortening a manufacturing cycle of the display panel to a certain extent and reducing a manufacturing cost of the display panel.

### Beneficial Effect of the Disclosure

### Beneficial Effect

When the LED chip is transferred to the chip soldering zone on the display backplane by using the chip transfer assembly provided in this application, for the to-be-transferred LED chip required for luminescent conversion, the luminescent conversion particle may be directly accommodated through the second pore of the colloid protrusion. After the LED chip is transferred to the chip soldering zone to complete soldering by using the colloid protrusion, the colloid protrusion having the luminescent conversion particle is separated from the porous adhesive layer on the transfer substrate and retains on the light-emitting surface of the LED chip, to form the luminescent conversion layer. That is to say, during the transferring of the LED chip to the chip soldering zone, the transferring of the chip and the manufacturing of a luminescent conversion layer are completed simultaneously. In this way, the luminescent conversion layer is no longer required to be separately manufactured after the LED chip is transferred to the chip soldering zone of a display backplane. Therefore, a manufacturing process of a display panel is simplified, manufacturing efficiency is enhanced, and a manufacturing cost is reduced.

### BRIEF DESCRIPTION OF THE DRAWINGS

FIG. 1 is a schematic diagram I of a chip transfer assembly according to an embodiment of the disclosure.

FIG. 2-1 is a schematic diagram of infiltrating the chip transfer assembly in FIG. 1 into luminescent conversion particles.

FIG. 2-2 is a schematic diagram after the chip transfer assembly in FIG. 1 is infiltrated into the luminescent conversion particles.

FIG. 3 is a schematic diagram II of a chip transfer assembly according to an embodiment of the disclosure.

FIG. 4 is a schematic diagram after the chip transfer assembly in FIG. 3 is infiltrated into the luminescent conversion particles.

FIG. 5 is a schematic diagram of a manufacturing process of a chip transfer assembly according to another optional embodiment of the disclosure.

FIG. 6-1 is a schematic diagram of a process of forming a porous adhesive layer according to another optional embodiment of the disclosure.

FIG. 6-2 is a schematic diagram of forming a porous adhesive layer obtained by another embodiment of the disclosure.

FIG. 7-1 is a schematic diagram of a process of forming a colloid protrusion according to another optional embodiment of the disclosure.

FIG. 7-2 is a schematic diagram of a colloid protrusion on a temporary transfer substrate obtained by another optional embodiment of the disclosure.

FIG. 7-3 is a schematic diagram of attaching a colloid protrusion on a temporary transfer substrate and a porous adhesive layer obtained by another optional embodiment of the disclosure.

FIG. 7-4 is a schematic diagram of separating a temporary transfer substrate from a colloid protrusion obtained by another optional embodiment of the disclosure.

FIG. 8 is a schematic cross-sectional view of a porous adhesive layer and a colloid protrusion according to another optional embodiment of the disclosure.

FIG. 9 is a schematic flowchart of a chip transfer method according to still another optional embodiment of the disclosure.

FIG. 10-1 is a schematic diagram of an LED chip on a growth substrate according to still another optional embodiment of the disclosure.

FIG. 10-2 is a top view of the LED chip on the growth substrate in FIG. 10-1.

FIG. 10-3 is a schematic diagram of attaching the LED chip on the growth substrate in FIG. 10-1 to an adhesion layer on a temporary transfer substrate.

FIG. 10-4 is a schematic diagram of an LED chip transferred to a temporary transfer substrate according to still another optional embodiment of the disclosure.

FIG. 10-5 is a top view after the LED chip in FIG. 10-4 is transferred to the temporary transfer substrate.

FIG. 11 is a schematic diagram I of a chip transfer process according to still another optional embodiment of the disclosure.

FIG. 12 is a schematic diagram II of a chip transfer process according to still another optional embodiment of the disclosure.

In the drawings:

1—Transfer substrate, 2—Porous adhesive layer, 21—First pore, 3—Colloid protrusion, 31—Second pore, 32—Contact surface between colloid protrusion and LED chip, 33—Contact surface between colloid protrusion and porous adhesive layer, 4—Luminescent conversion particle, 5—Temporary transfer substrate, 6—Temporary substrate, 7—LED chip, 8—Display backplane, 9—Solder, 10—Base substrate, 101—Temporary substrate coverage area, 11—Adhesion layer.

### DETAILED DESCRIPTION OF THE EMBODIMENTS

### Embodiments of the Disclosure

For easy of understanding this application, this application will be described in detail below with reference to the related drawings. The preferred implementations of this application are shown in the accompanying drawings. However, this application may be implemented in many different forms, and is not limited to the implementations described herein. Rather, the purpose of providing the implementations is to understand the disclosure of this application more thoroughly and completely.

Unless otherwise defined, all technical and scientific terms in the specification have the same meaning as those skilled in the art, belonging to this application, usually understand. The terms used herein in the specification of this application are for the purpose of merely describing specific implementations, and are not intended to limit this application.

In the prior art, when a display panel is manufactured, a blue LED chip is first transferred to a display backplane, and then a film for luminescent conversion is separately manufactured on the corresponding blue LED chip. A process is relatively tedious, and efficiency is low, resulting a high manufacturing cost of a display panel.

Based on this, this application is intended to provide a solution that can resolve the above technical problems, details of which will be described in the subsequent embodiments.

A chip transfer assembly in this embodiment includes a transfer substrate, a porous adhesive layer is formed on the transfer substrate. First pores are distributed in the porous adhesive layer. At least one colloid protrusion is formed on the porous adhesive layer. The colloid protrusion has a light transmittance. Second pores are distributed in the colloid protrusion. A size of each second pore matches a size of a luminescent conversion particle and the size of each second pore is less than a size of each first pore. The size of the second pore is less than the size of the first pore in the porous adhesive layer.

When the chip transfer assembly in this embodiment is used to transfer a chip, and when a to-be-transferred LED chip is a chip required for luminescent conversion, a luminescent conversion particle is first disposed in the second pore of the colloid protrusion. Then the colloid protrusion is attached to a light-emitting surface of the to-be-transferred LED chip. The colloid protrusion adsorbs the LED chip under the action of heating after cooling, so that the to-be-transferred LED chip is adsorbed and picked up to transfer to a corresponding chip soldering zone. Then the LED chip is soldered by means of, but not limited to, heating. During this process, a separation surface is formed on a contact surface between the colloid protrusion and the porous adhesive layer under a heat effect, the colloid protrusion is separated from the porous adhesive layer and retained on the light-emitting surface of the LED chip. In addition, since the luminescent conversion particles are distributed in the second pores of the colloid protrusion, the colloid protrusion is formed into a luminescent conversion layer (may also be known as a luminescent conversion film) disposed on the light-emitting surface of the LED chip. That is to say, the chip transfer assembly in this embodiment may be used as a transfer head during the transferring of the LED chip. After the LED chip is transferred to the chip soldering zone for soldering, the colloid protrusion is separating from the porous adhesive layer and retained on the light-emitting surface of the LED chip as the luminescent conversion layer of the LED chip. That is to say, during the transferring of the LED chip to the chip soldering zone, the transferring of the chip and the manufacturing of a luminescent conversion layer are completed simultaneously. In this way, the luminescent conversion layer is no longer required to be separately manufactured after the LED chip is transferred to the chip soldering zone of a display backplane. Therefore, a manufacturing process of a display panel is simplified, manufacturing efficiency is enhanced, and a manufacturing cost is reduced.

It is to be understood that, if the to-be-transferred LED chip is an LED chip that is not required for luminescent conversion, the luminescent conversion particle may not be disposed in the second pore of the colloid protrusion, and the corresponding colloid protrusion is directly attached to the light-emitting surface of the LED chip. In this way, the LED chip is transferred to the chip soldering zone for soldering by means of the above similar transfer process. Definitely, it is also be understood that, other various LED chip transfer methods may also be used for the LED chip that is not required for luminescent conversion, which is not described herein again.

It is to be understood that, the LED chip in this embodiment may be an LED chip with a common size, or may be a micro-LED chip. When the LED chip is the micro-LED chip, the LED chip may include, but is not limited to, at least one of a micro-LED chip or a mini-LED chip. For example, in an example, the micro-LED chip may be the micro-LED chip. In another example, the micro-LED chip may be the mini-LED chip.

It is to be understood that, the LED chip in this embodiment may include, but is not limited to, at least one of a flip chip LED chip or a normal LED chip. For example, in an example, the LED chip may be the flip chip LED chip. In another example, the LED chip may be the normal LED chip.

In an example of this embodiment, the LED chip may include, but is not limited to, an epitaxial layer and an electrode. A specific structure of the epitaxial layer of the LED chip is not limited in this embodiment. In an example, the epitaxial layer of the LED chip may include an N-type semi-conductor, a P-type semi-conductor, and an active layer located between the N-type semi-conductor and the P-type semi-conductor. The active layer may include a quantum well layer, or may include other structures. In some other examples, optionally, the epitaxial layer may further include at least one of a reflective layer or a passivation layer. In this embodiment, a material and shape of the electrode are not limited. For example, the material of the electrode may include, but is not limited to, at least one of Cr, Ni, Al, Ti, Au, Pt, W, Pb, Rh, Sn, Cu, or Ag.

It is to be understood that, a specific distribution quantity (that is, a porosity of the porous adhesive layer (and a ratio of a volume occupied by the pores to a total volume of the porous adhesive layer)) that the first pores distributed in the porous adhesive layer may be flexibly set according to a specific application scenario. For example, the porosity may be set to, but is not limited to, 25%, 30%, or 40%. The size of the first pore may also be flexibly set according to specific application requirements. For example, in some application example, the size of the first pore may be set to, but not limited to, a range of 50 nanometers to 1000 nanometers. During specific application, the size of the first pore may be set to 50 nanometers, 100 nanometers, 200 nanometers, 300 nanometers, 500 nanometers, 600 nanometers, 750 nanometers, 800 nanometers, 900 nanometers, or 1000 nanometers according to requirements. In addition, it is to be understood that, the sizes of the plurality of first pores distributed in the porous adhesive layer may be same or different.

Likewise, it is to be understood that, in this embodiment, a specific distribution quantity (that is, a porosity of the colloid protrusion) that the second pores distributed in the colloid protrusion may be flexibly set according to a specific application scenario. For example, the porosity of the colloid protrusion may be set to, but is not limited to, 25%, 35%, or 40%, which may be the same or different from the porosity of the porous adhesive layer. The size of the second pore may also be flexibly set according to the specific application requirements, for example, may be flexibly set according to a size of specifically used luminescent conversion particle. The luminescent conversion particle may be a quantum dot (QD) particle, or a phosphor particle, or other particles that achieve luminescent conversion. For example, in some application example, the size of the second pore may be set to, but not limited to, a range of 6 nanometers to 30 nanometers. During specific application, the size of the first pore may be set to 6 nanometers, 8 nanometers, 10 nanometers, 11 nanometers, 15 nanometers, 18 nanometers, 20 nanometers, 25 nanometers, 28 nanometers, or 30 nanometers according to requirements. In addition, it is to be understood that, the sizes of the plurality of second pores distributed in the colloid protrusion may be the same or different.

It is to be understood that, in this embodiment, a material and shape of the transfer substrate are not limited. For example, the transfer substrate may be, but not limited to, any of glass, sapphire, quartz, or silicon. In this embodiment, the material of the porous adhesive layer may further be selected flexibly. For example, in an application scenario, the porous adhesive layer may be, but not limited to, a Polydimethylsiloxane (PDMS) system adhesive layer. Likewise, in this embodiment, the material of the colloid protrusion may further be selected flexibly. For example, in an application scenario, the material of the colloid protrusion may be, but not limited to, an organic silicone system colloid or acrylic resin. For example, in an example, the material of the colloid protrusion may further be the PDMS system colloid, or be other organic silicone system colloid.

It is to be understood that, in this embodiment, a quantity of the colloid protrusion formed on the porous adhesive layer may be set flexibly according to a specific application scenario. For example, with regard to an application scenario of transferring a single LED chip for a single time, the single colloid protrusion may be formed on the porous adhesive layer, or a plurality of colloid protrusions may be formed but are used one by one during transferring. For the application scenario of transferring the single LED chip for the single time, the plurality of colloid protrusions may be formed on the porous adhesive layer. The position distribution of the plurality of colloid protrusions on the porous adhesive layer corresponds to the position distribution of a plurality of to-be-transferred LED chips. That is to say, the plurality of colloid protrusions are formed according to the patterning of the plurality of to-be-transferred LED chips.

It is to be understood that, in this embodiment, the shape of the colloid protrusion may be designed flexibly, for example, may be designed as a regular shape (for example, a cylindrical shape, or a rectangular shape), or may be designed as an irregular shape. In some other application examples of this embodiment, for ease of separation of the colloid protrusion from the porous adhesive layer, an area of the contact surface between the colloid protrusion and the porous adhesive layer is less than an area of a contact surface between the colloid protrusion and the LED chip. In this application example, a cross section of the colloid protrusion in a height direction may be, but not limited to, in a trapezoid shape, or may be other any shape meeting the above condition.

For ease of understanding, in this embodiment, the chip transfer assembly provided in this embodiment is illustrated below with reference to the accompanying drawings.

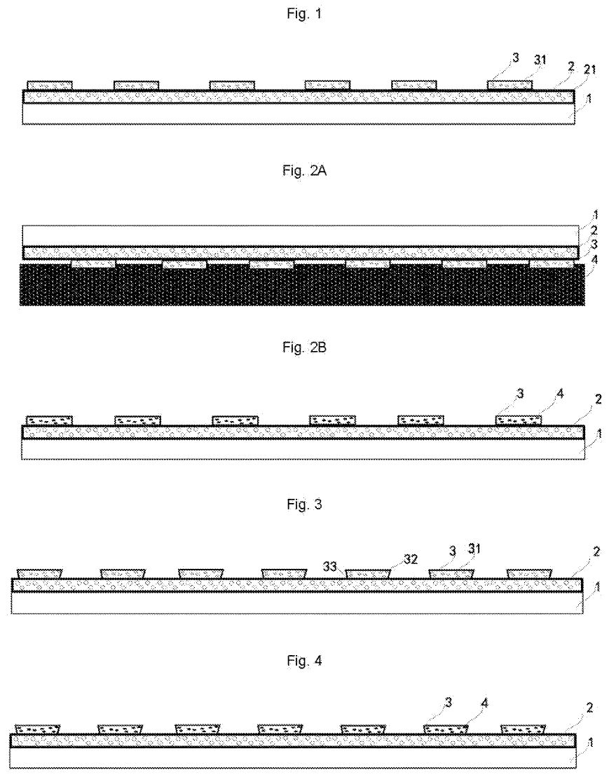

Referring to an example shown in FIG. 1, the chip transfer assembly in this example includes a transfer substrate 1 and a porous adhesive layer 2. The porous adhesive layer 2 is disposed on the transfer substrate 1. First pores 21 are distributed in the porous adhesive layer 2. The chip transfer assembly further includes a plurality (or may be set as a single according to requirements) of colloid protrusions 3 disposed on the porous adhesive layer 2. Second pores 31 are distributed in the colloid protrusions 3. The sizes of the second pores 31 are less than that of the first pores 21. The colloid protrusions 3 have a light transmittance. An section of the colloid protrusions 3 shown in FIG. 1 in the height direction is in a rectangular shape. Definitely, the interface may be designed into other shapes according to requirements, which is not described herein again.

In some application scenarios, when luminescent conversion is required to be performed on the to-be-transferred LED chip such as the blue LED chip, the blue LED chip needs to be converted to red or green application scenarios. Before the chip transfer assembly shown in FIG. 1 transfers the blue LED chip, the corresponding luminescent conversion particle (for example, blue light is converted into a red luminescent conversion particle, or the blue light is converted into a green luminescent conversion particle) may be disposed in the second pore 31 of the corresponding colloid protrusion 3. An arrangement example is shown in FIG. 2-1, the colloid protrusion 3 of the chip transfer assembly may be infiltrated into the luminescent conversion particles 4 to allow the luminescent conversion particles 4 to enter the second pores 31, so as to finally obtain the chip transfer assembly shown in FIG. 2-2. Then, the blue LED chip may be transferred according to the above example manner by using the chip transfer assembly shown in FIG. 2-2. In addition, the colloid protrusion 3 with the luminescent conversion particles distributed inside is finally retained on the light-emitting surface of the blue LED chip as the luminescent conversion layer of the blue LED chip, so as to convert the emitted blue light into required red light, green light, or light with other colors.

Referring to an example shown in FIG. 3, the chip transfer assembly in this example further includes a transfer substrate 1 and a porous adhesive layer 2. The porous adhesive layer is disposed on the transfer substrate 1. First pores 21 are distributed in the porous adhesive layer 2. The chip transfer assembly further includes a plurality (or may be set as a single according to requirements) of colloid protrusions 3 disposed on the porous adhesive layer 2. Second pores 31 are distributed in the colloid protrusions 3. The sizes of the second pores 31 are less than that of the first pores 21. The colloid protrusions 3 has a light transmittance. An section of the colloid protrusions 3 shown in FIG. 2 in the height direction is in a trapezoid shape. An area of a contact surface 33 between the colloid protrusion 3 and the porous adhesive layer 2 is less than an area of a contact surface 32 between the colloid protrusion 3 and the LED chip. In this way, the colloid protrusion 3 can be separated from the porous adhesive layer 2 more conveniently and retained on the light-emitting surface of the LED chip as the luminescent conversion layer. A form of the luminescent conversion particle is designed in the porous adhesive layer 2 according to requirements, as shown in FIG. 4.

It is to be understood that, in this embodiment, the formation process of the porous adhesive layer and the colloid protrusion of the above examples may be selected flexibly, which is not limited in this embodiment.

### Another Optional Embodiment of the Disclosure

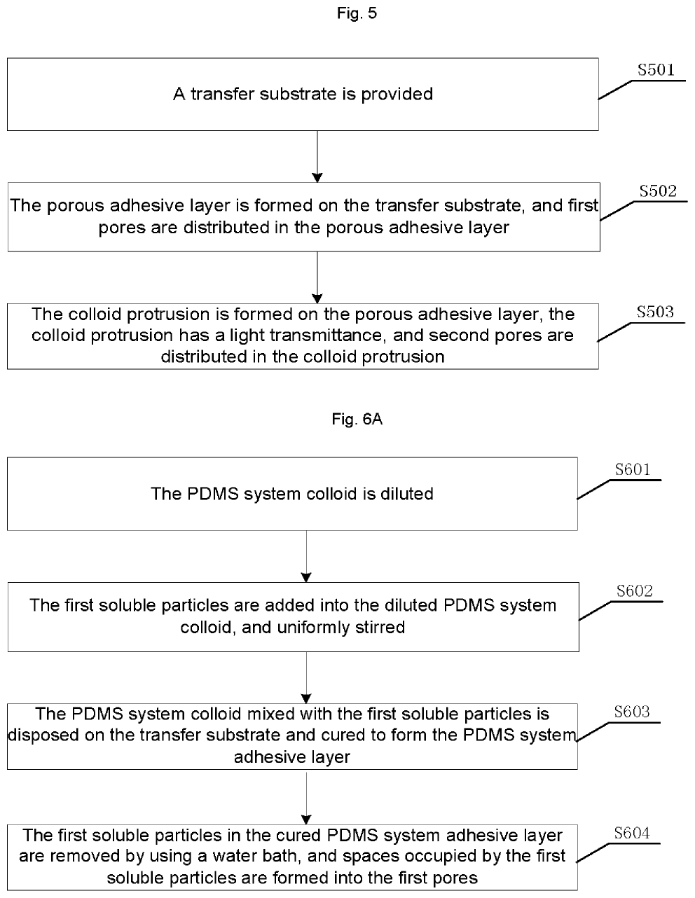

For ease of understanding, this embodiment provides a method for manufacturing an exemplary chip transfer assembly. As shown in FIG. 5, the method includes, but is not limited to, the following operations.

At S501, a transfer substrate is provided. In this embodiment, a material and shape of the transfer substrate are not limited. For example, the transfer substrate may be, but not limited to, any of glass, sapphire, quartz, or silicon.

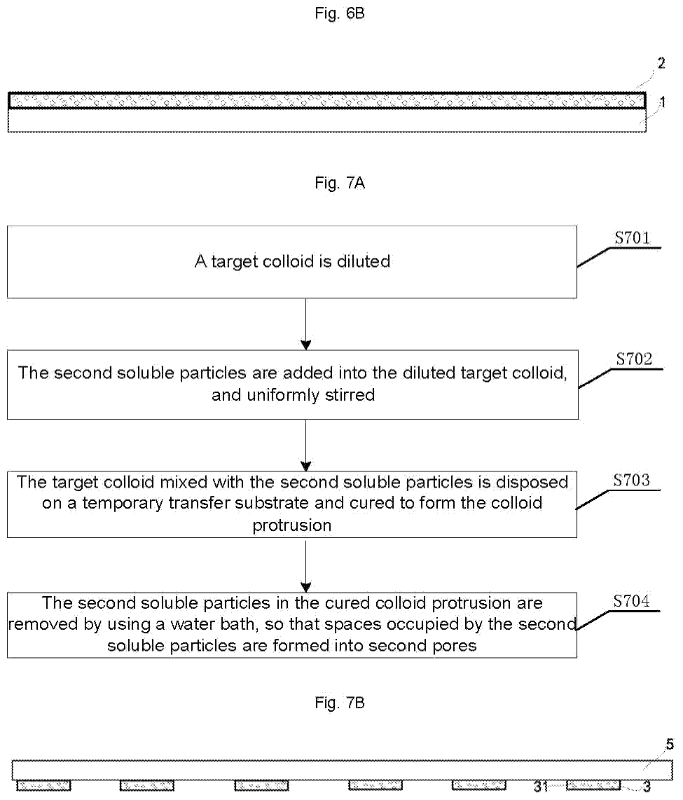

At S502, the porous adhesive layer is formed on the transfer substrate. First pores are distributed in the porous adhesive layer. A material and a formation process of the porous adhesive layer may be flexibly selected. For example, in an example, the porous adhesive layer is a PDMS system adhesive layer. A formation process of an example is shown in FIG. 6-1, and includes, but is not limited to, the following operations.

At S601, PDMS system colloid is diluted. For example, the PDMS system colloid may be diluted by using, but not limited to, xylene. After dilution, it is convenient to disperse first soluble particles and avoid agglomeration as much as possible.

At S602, the first soluble particles are added into the diluted PDMS system colloid, and uniformly stirred.

The selected first soluble particles have the property of being soluble at a certain temperature. For example, the first soluble particles may include, but are not limited to, at least one of sugar particles (such as glucose particles or sucrose particles) or salt particles (such as sodium chloride particles). Sizes of the selected first soluble particles may be flexibly selected according to requirements for the to-be-formed first pores, for example, the first soluble particles with the sizes ranging from 50 nanometers to 1000 nanometers may be correspondingly selected.

At S603, the PDMS system colloid mixed with the first soluble particles is disposed on the transfer substrate and cured to form the PDMS system adhesive layer.

In some examples, the PDMS system colloid mixed with the first soluble particles may be coated on the transfer substrate by using, but not limited to, a coating manner (for example, a spincoating manner). A thickness of coating may be flexibly set according to requirements. After coating, it may adopt, but is not limited to, thermal curing (for example, by placing the PDMS system colloid at 80° C. for 30 minutes).

At S604, the first soluble particles in the cured PDMS system adhesive layer are removed by using a water bath. Spaces occupied by the first soluble particles are formed into the first pores.

The water bath in this example is a heating method in a chemistry laboratory that uses water as a heat transfer medium. A container of a heated substance is put into the water. A boiling point of the water is 100° C. The method is suitable for a heating temperature below 100° C. The mixed first soluble particles (such as the sugar particles or the salt particles) can be dissolved under a certain temperature, so that the spaces that are originally occupied by the first soluble particles are vacated to form the first pores. The obtained porous adhesive layer is shown in FIG. 6-2. The first pores are distributed in the porous adhesive layer 2 formed on the transfer substrate 1. The porosity of the first pores in the porous adhesive layer 2 obtained in this example is about 30%.

At S503, the colloid protrusion is formed on the porous adhesive layer. The colloid protrusion has a light transmittance. Second pores are distributed in the colloid protrusion. A size of each second pore matches a size of a luminescent conversion particle and is less than a size of each first pore.

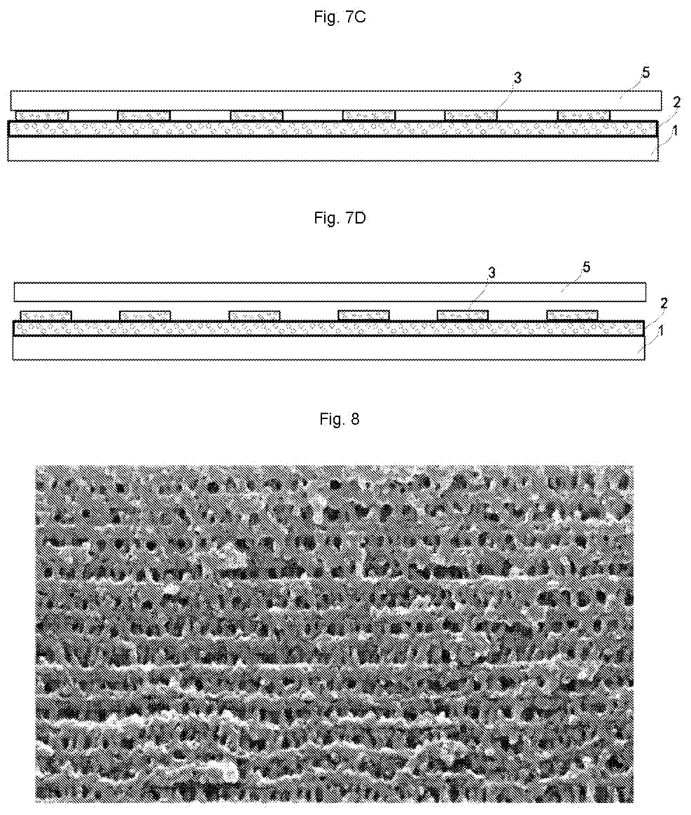

A material and a formation process of the colloid protrusion may be flexibly selected. A formation process of an example is shown in FIG. 7, and includes, but is not limited to, the following operations.

At S701, a target colloid is diluted.

The target colloid may be an organic silicone system colloid or acrylic resin. For example, the target colloid may be diluted by using, but not limited to, xylene. After dilution, it is convenient to disperse second soluble particles and avoid agglomeration as much as possible.

At S702, the second soluble particles are added into the diluted target colloid, and uniformly stirred.

The selected second soluble particles have the property of being soluble at a certain temperature. For example, the second soluble particles may include, but are not limited to, at least one of sugar particles (such as glucose particles or sucrose particles) or salt particles (such as sodium chloride particles). Sizes of the selected second soluble particles may be flexibly selected according to requirements for the to-be-formed second pores, for example, the second soluble particles with the sizes ranging from 6 nanometers to 30 nanometers may be correspondingly selected. The sizes of the second soluble particles are less than that of the first soluble particles.

At S703, the target colloid mixed with the second soluble particles is disposed on a temporary transfer substrate and cured to form the colloid protrusion.

In some examples, the target colloid mixed with the second soluble particles may be coated on the temporary transfer substrate by using, but not limited to, a coating manner (for example, a spincoating manner). A thickness of coating may be flexibly set according to requirements. After coating, the target colloid may be cured by using, but not limited to, manners of thermal curing (for example, by placing the target colloid at 80° C. for 30 minutes), or ultraviolet curing. Then the corresponding colloid protrusion is formed through manners such as cutting or etching.

At S704, the second soluble particles in the cured colloid protrusion are removed by using a water bath, so that spaces occupied by the second soluble particles are formed into second pores. An example structure is shown in FIG. 7-2, the colloid protrusion 3 is formed on the temporary transfer substrate 5. The second pores 31 are distributed in the colloid protrusion 3.

At S705, the colloid protrusion on the temporary transfer substrate is attached to the porous adhesive layer on the transfer substrate, and the temporary transfer substrate is separated from the colloid protrusion, so that the colloid protrusion is formed on the porous adhesive layer.

An example process is shown in FIG. 7-3 and FIG. 7-4. The colloid protrusion 3 formed on the temporary transfer substrate 5 is attached to the porous adhesive layer 2 on the transfer substrate 1. Then the temporary transfer substrate 5 is separated from the colloid protrusion 3, and the colloid protrusion 3 is retained on the porous adhesive layer 2.

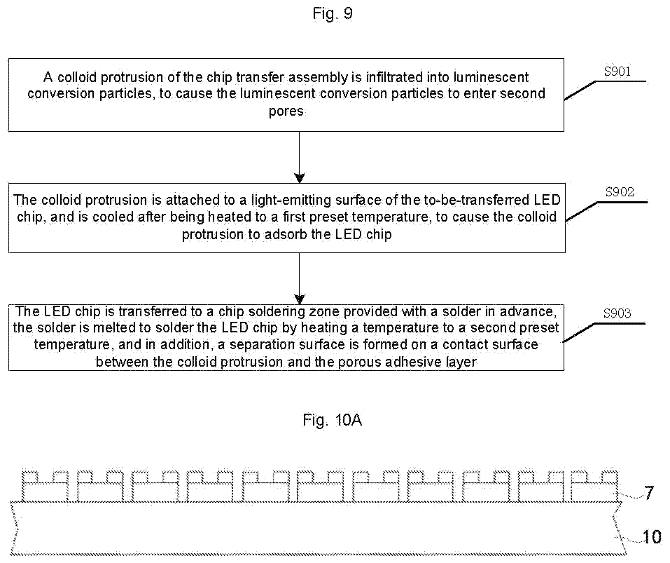

In this example, FIG. 8 is an enlarged cross-sectional view of an obtained porous adhesive layer and colloid protrusion physical product, with pores distributed inside and a shape similar to sponge.

It is to be understood that, the above method for manufacturing a chip transfer assembly is merely an exemplary method for manufacturing a chip transfer assembly in this embodiment, and the manufacturing of the chip transfer assembly in this embodiment is not limited to the above exemplary method. However, it can be learned from the above example method that, the chip transfer assembly in this embodiment is simple and convenient in manufacturing, high in manufacturing efficiency, and low in cost.

Still another optional embodiment of the disclosure:

For ease of understanding, in this embodiment, a method for transferring a chip by using the above chip transfer assembly is illustrated below. Referring to FIG. 9, the method includes the following operations.

At S901, a colloid protrusion of the chip transfer assembly is infiltrated into luminescent conversion particles, to cause the luminescent conversion particles to enter second pores.

It is to be understood that, when a to-be-transferred LED chip is a chip that is not required for luminescent conversion, a next operation is directly performed. Definitely, other chip transfer methods may further be used to transfer the LED chip, which are not described herein again.

At S902, the colloid protrusion is attached to a light-emitting surface of the to-be-transferred LED chip, and is cooled after being heated to a first preset temperature, to cause the colloid protrusion to adsorb the LED chip, so as to pick up the LED chip.

In this embodiment, before the colloid protrusion is attached to the light-emitting surface of the to-be-transferred LED chip (or definitely, after the colloid protrusion is attached to the light-emitting surface of the to-be-transferred LED chip), the chip transfer assembly (in this case, used as a transfer head) is heated to the first preset temperature, so that the porous adhesive layer and a porous material of the colloid protrusion are in a state that a gas density is relatively low, and a volume is relatively large. Then, the colloid protrusion is attached to the light-emitting surface of the to-be-transferred LED chip. Under a thermal condition, the colloid protrusion is in contact with the LED chip. After contact, the temperature starts to reduce to cool gas in pores of the porous adhesive layer and the porous material of the colloid protrusion, and the gas volume shrinks. In this way, in an aspect, the colloid of the colloid protrusion adheres to the LED chip through hydrogen bonds or Van der Waals force, and in another aspect, the pressure of the gas before and after the volume shrinks changes to increase the adhesion of the colloid to the LED chip. Then, the LED chip is striped off from a temporary substrate or a growth base substrate on which the LED chip is located to pick up the LED chip. In this embodiment, the first preset temperature may be, but not limited to, a range of 60° C. to 80° C. For example, the first preset temperature may be set to 60° C., 65° C., 75° C., 80° C., or the like.

At S903, the LED chip picked up by the colloid protrusion is transferred to a chip soldering zone provided with a solder in advance. The solder is melted to solder the LED chip by heating a temperature to a second preset temperature. In addition, a separation surface is formed on a contact surface between the colloid protrusion and the porous adhesive layer under the action of a heat effect, so as to separate the colloid protrusion from the porous adhesive layer and retain the colloid protrusion on the light-emitting surface of the LED chip.

In this embodiment, after the LED chip picked up by the colloid protrusion is transferred to the chip soldering zone provided with the solder in advance, the temperature is heated up again to rise the overall temperature, so that the solder is melted to solder the LED chip and a backplane circuit pad. In addition, during the process, the temperature is risen, since the first pores of the porous adhesive layer are greater than the second pores of the colloid protrusion, and the porous adhesive layer and the porous material of the colloid protrusion are in the state of a relative low gas density and relative large volume, a mutually repulsive force is generated as the volume between the porous adhesive layer and the porous material of the colloid protrusion increases. When separation is achieved under a heat effect, the separation surface is formed on the contact surface of the porous adhesive layer and the colloid protrusion, so that a binding force between the porous adhesive layer and the colloid protrusion is less than a binding force between the colloid protrusion and the LED chip. Therefore, the colloid protrusion may be successfully separated from the porous adhesive layer. In this way, the colloid protrusion infiltrated with the luminescent conversion particles are retained on the LED chip by means of the Van der Waals force as the luminescent conversion layer of the LED chip for color conversion.

In this embodiment, considering the thermal endurance of the luminescent conversion particles (such as a QD material), it may adopt, but is not limited to, the solder with relatively high bismuth content during soldering. The corresponding second preset temperature may be set to, but is not limited to, a range of 90° C. to 100° C. For example, the second preset temperature may be set to 90° C., 92° C., 95° C., or 100° C.

For easy of understanding, in this embodiment, a transfer process of a flip chip LED chip is exemplarily described with an application example below with reference to the accompanying drawings.

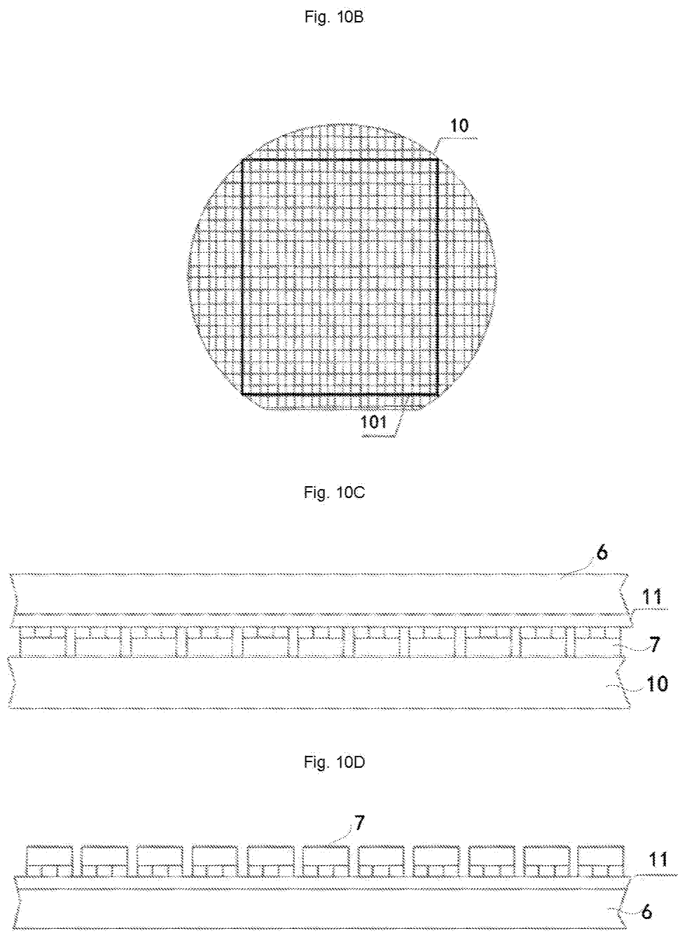

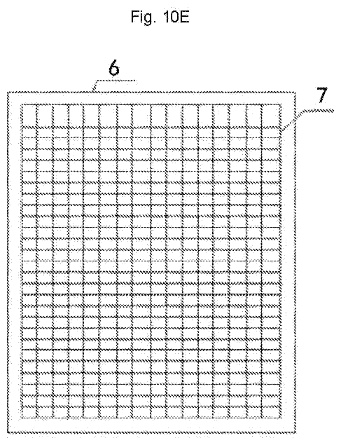

In this example, referring to FIG. 10-1 to FIG. 10-2, an LED chip 7 is grown on the growth substrate 10. An area shown in a black line frame 101 in FIG. 10-2 is an area covered (that is, selected) by the temporary substrate. Referring to FIG. 10-3 to FIG. 10-5, in this embodiment, the adhesion layer 11 is disposed on the temporary substrate 6. An arrangement form of the adhesion layer 11 may be designed flexibly, as long as it satisfies that the corresponding LED chip is reliably adhered when the adhesion layer is attached to a side on which a plurality of micro-LED chips are grown on the growth substrate. Referring to FIG. 10-3, the adhesion layer 11 on the temporary substrate 6 is attached to a to-be-transferred LED chip 7 to bond the LED chip. The LED chip 7 is striped off from the growth substrate 10 and then transferred to the temporary substrate 6. Referring to FIG. 10-4 and FIG. 10-5, FIG. 10-5 is a top view of the temporary substrate 11. In this process, it may further adopt, but not limited to, Laser Lift Off (LLO) to guarantee the LED chip to successfully strip off from the growth substrate.

It is to be understood that, in this embodiment, a material of the growth substrate is a semiconductor material that can grow an epitaxial layer of the micro-LED chip on the growth substrate. For example, the material of the growth substrate may be, but not limited to, sapphire, silicon carbide, silicon, or gallium arsenide, and may also be other semiconductor materials, which is not limited herein.

A material of the temporary substrate is not limited in this embodiment. For example, in an example, the material of the temporary substrate may be, but not limited to, any of glass, sapphire, quartz, or silicon.

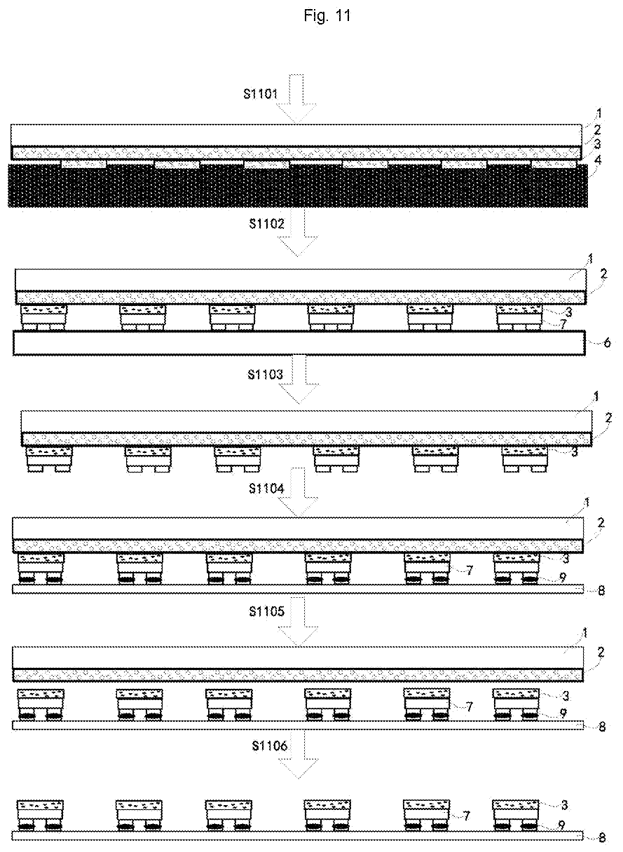

In this application example, the LED chip is the blue LED ship, and the luminescent conversion particle is a red QD particle or a green QD particle, for example. For example, assuming that some blue LED chips need to be converted into red light on the display backplane, a transfer process may be seen in FIG. 11 and includes the following operations.

At S1101, the colloid protrusion 3 of the chip transfer assembly is infiltrated into the red QD particle, to obtain the colloid protrusion 3 with the red QD particles distributed in the second pores 31.

At S1102, the colloid protrusion 3 of the chip transfer assembly is heated to the first preset temperature, and then the colloid protrusion is attached to the corresponding LED ship 7 (it is the blue LED chip in this example) on the temporary substrate 6.

At S1103, the colloid protrusion 3 is cooled to cause the colloid protrusion 3 to adsorb the LED chip 7, so as to pick up the LED chip 7.

At S1104, the LED chip 7 picked up by the colloid protrusion 3 is transferred to the corresponding chip soldering zone on the display backplane 8, and a pad of the chip soldering zone is provided with the solder 9.

At S1105, the solder 9 is melted to solder the LED chip by heating a temperature to a second preset temperature. In addition, a separation surface is formed on a contact surface between the colloid protrusion and the porous adhesive layer under the action of a heat effect, so as to separate the colloid protrusion from the porous adhesive layer and retain the colloid protrusion on the light-emitting surface of the LED chip. In an example, after cooling, since the LED chip is soldered on the pad of the soldering zone, the transfer substrate can be lifted upward. Since the separation surface is formed between the colloid protrusion and the porous adhesive layer, an adhesive force between the colloid protrusion and the porous adhesive layer is less than an adhesive force between the LED chip and the colloid protrusion, so that the colloid protrusion is separated from the porous adhesive layer and retained on the light-emitting surface of the LED chip.

At S1106, an LED that emits red light on the display backplane is finally obtained.

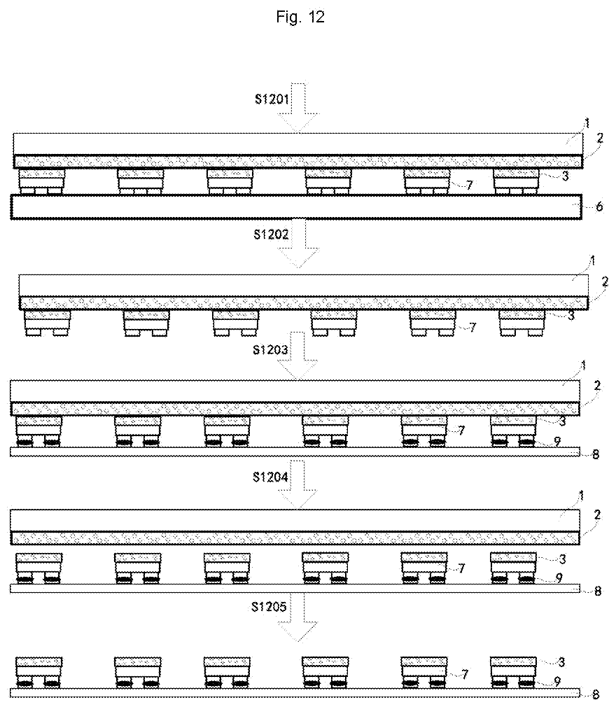

In some application examples, when luminescent conversion does not required to be performed on the blue LED chip, a transfer process of an example is shown in FIG. 12 and includes the following operations.

At S1201, the colloid protrusion 3 (having no luminescent conversion particles in the internal second pores) of the chip transfer assembly is heated to the first preset temperature, and then the colloid protrusion is attached to the corresponding LED ship 7 (it is the blue LED chip in this example) on the temporary substrate 6.

At S1202, the colloid protrusion 3 is cooled to cause the colloid protrusion 3 to adsorb the LED chip 7, so as to pick up the LED chip 7.

At S1203, the LED chip 7 picked up by the colloid protrusion 3 is transferred to the corresponding chip soldering zone on the display backplane 8, and a pad of the chip soldering zone is provided with the solder 9.

At S1204, the solder 9 is melted to solder the LED chip by heating a temperature to a second preset temperature. In addition, a separation surface is formed on a contact surface between the colloid protrusion and the porous adhesive layer under the action of a heat effect, so as to separate the colloid protrusion from the porous adhesive layer and retain the colloid protrusion on the light-emitting surface of the LED chip.

At S1205, an LED that emits blue light on the display backplane is finally obtained.

Definitely, when luminescent conversion does not require to be performed on the blue LED chip, a transfer manner of the blue LED chip may adopt various conventional transfer manners, and is not limited to the transfer manner shown in FIG. 12.

After the LED chip is transferred to a blue chip for three times by means of the above transfer manner, different colors may be displayed. In this way, the tedious process of manufacturing a QD film separately later is avoided, and a process of manufacturing a color display panel can be simplified.

This embodiment further provides a display panel. The display panel includes a display backplane and a plurality of LED chips. A plurality of chip soldering zones are disposed on the display backplane. The plurality of LED chips are respectively transferred to the chip soldering zones to achieve bonding by means of the chip transfer method shown above. Since the tedious process of manufacturing the luminescent conversion layer separately later is avoided, and a process of manufacturing the display panel is simplified, the manufacturing efficiency of the display panel can be enhanced, and costs can be reduced.

It is to be understood that, the application of the disclosure is not limited to the above examples, for those of ordinary skill in the art, improvements or transformations may be made according to the above description; and these improvements or transformations shall fall within the protection scope of the appended claims of the present disclosure.

What is claimed is:

1. A chip transfer assembly, comprising:
a transfer substrate;
a porous adhesive layer formed on the transfer substrate, first pores being distributed in the porous adhesive layer; and
at least one colloid protrusion formed on the porous adhesive layer, the colloid protrusion having light transmittance, and second pores being distributed in the colloid protrusion, wherein a size of each second pore matches a size of a luminescent conversion particle, and the size of each second pore is less than a size of each first pore;
wherein the second pore is configured to accommodate the luminescent conversion particle during transfer of a Light-Emitting Diode (LED) chip; the colloid protrusion is configured to be attached to a light-emitting surface of a to-be-transferred LED chip and then to adsorb the LED chip under the action of cooling after heating during transfer of the LED chip, and is further configured to form a separation surface on a surface that is in contact with the porous adhesive layer during soldering of the heated LED chip after the adsorbed LED chip is transferred to a chip soldering zone, so as to separate from the porous adhesive layer and retain on the light-emitting surface of the LED chip.

2. The chip transfer assembly according to claim 1, wherein a plurality of colloid protrusions are formed on the porous adhesive layer, and position distribution of the plurality of colloid protrusions on the porous adhesive layer corresponds to position distribution of a plurality of to-be-transferred LED chips.

3. The chip transfer assembly according to claim 1, wherein the size of the first pore ranges from 50 nanometers to 1000 nanometers, and the size of the second pore ranges from 6 nanometers to 30 nanometers.

4. The chip transfer assembly according to claim 1, wherein an area of a contact surface between the colloid protrusion and the porous adhesive layer is less than an area of a contact surface between the colloid protrusion and the LED chip.

5. The chip transfer assembly according to claim 4, wherein a cross section of the colloid protrusion in a height direction is in a trapezoid shape.

6. The chip transfer assembly according to claim 1, wherein the porous adhesive layer comprises a Polydimethylsiloxane (PDMS) system adhesive layer.

7. The chip transfer assembly according to claim 1, wherein the colloid protrusion comprises an organic silicone system colloid or an acrylic resin.

8. A method for manufacturing a chip transfer assembly according to claim 1, comprising:
providing the transfer substrate;
forming the porous adhesive layer on the transfer substrate, first pores being distributed in the porous adhesive layer; forming the colloid protrusion on the porous adhesive layer, the colloid protrusion having light transmittance, and second pores being distributed in the colloid protrusion, wherein the size of each second pore matches the size of the luminescent conversion particle and is less than the size of each first pore.

9. The method for manufacturing a chip transfer assembly according to claim 8, wherein the porous adhesive layer comprises a PDMS system adhesive layer, and
the forming the porous adhesive layer on the transfer substrate comprises:
diluting the PDMS system colloid;
adding a first soluble particle into the diluted PDMS system colloid to uniformly stir;
disposing the PDMS system colloid mixed with the first soluble particle on the transfer substrate for curing, to form the PDMS system adhesive layer; and
removing the first soluble particle in the cured PDMS system adhesive layer by using a water bath, a space occupied by the first soluble particle forming the first pore.

10. The method for manufacturing a chip transfer assembly according to claim 9, wherein the forming the colloid protrusion on the porous adhesive layer comprises:
diluting a target colloid, the target colloid comprises an organic silicone system colloid or an acrylic resin;
adding a second soluble particle into the diluted target colloid to uniformly stir;
disposing the target colloid mixed with the second soluble particle on the temporary transfer substrate for curing, to form the colloid protrusion;
removing the second soluble particle in the cured colloid protrusion by using a water bath, a space occupied by the second soluble particle forming the second pore; and
attaching the colloid protrusion on the temporary transfer substrate to the porous adhesive layer on the transfer substrate, and separating the temporary transfer substrate from the colloid protrusion.

11. The method for manufacturing a chip transfer assembly according to claim 10, wherein a diameter of the first soluble particle is greater than a diameter of the second soluble particle; and
the first soluble particle and the second soluble particle both comprise at least one of sugar particles or salt particles.

12. A chip transfer method, comprising:
infiltrating a colloid protrusion of the chip transfer assembly according to claim 1 into luminescent conversion particles, to cause the luminescent conversion particles to enter second pores;
attaching the colloid protrusion to a light-emitting surface of a to-be-transferred Light-Emitting Diode (LED) chip, cooling the colloid protrusion after heating to a preset temperature, to cause the colloid protrusion to adsorb the LED chip, so as to pick up the LED chip; and
transferring the LED chip picked up by the colloid protrusion to a chip soldering zone provided with a solder in advance, heating a temperature to a second preset temperature to melt the solder to solder the LED chip, and forming a separation surface on a contact surface between the colloid protrusion and the porous adhesive layer under the action of a heat effect during this process, so as to separate the colloid protrusion from the porous adhesive layer and retain the colloid protrusion on the light-emitting surface of the LED chip.

13. The chip transfer method according to claim 12, wherein the first preset temperature ranges from 60° C. to 80° C., and the second preset temperature ranges from 90° C. to 100° C.

14. The chip transfer method according to claim 12, wherein the luminescent conversion particle comprises a red quantum dot (QD) particle or a green QD particle.

15. A display panel, comprising a display backplane and a plurality of Light-Emitting Diode (LED) chips, wherein a plurality of chip soldering zones are disposed on the display backplane, and the plurality of LED chips are respectively transferred to the chip soldering zones to achieve bonding by means of the chip transfer method according to claim 12.

16. The chip transfer assembly according to claim 1, wherein the LED chip comprises a micro-LED chip or a mini-LED chip.

17. The chip transfer assembly according to claim 1, wherein the LED chip comprises a flip chip LED chip or a formal LED chip.

18. The chip transfer assembly according to claim 1, wherein the transfer substrate comprises any one of glass or sapphire.

19. The method for manufacturing a chip transfer assembly according to claim 9, wherein the PDMS system colloid mixed with the first soluble particles is coated on the transfer substrate by using a coating manner.

20. The method for manufacturing a chip transfer assembly according to claim 10, wherein the target colloid mixed with the second soluble particles is coated on the temporary transfer substrate by using a coating manner.
